(19) United States
(12) Patent Application Publication
(10) Pub. No.: US 2006/0125074 A1
(43) Pub. Date: Jun. 15, 2006

(54) Method of connecting internal silver traces to external gold to produce a gold external side metal for an LTCC package

(76) Inventors: Phillip S. Fisher, Attica, IN (US); James E. Elsner, Lafayette, IN (US); Dean A. Marshall, Lafayette, IN (US)

Correspondence Address: CTS CORPORATION, 905 W. BLVD. N, ELKHART, IN, 46514, US

(21) Appl. No.: 11/012,561

(22) Filed: Dec. 15, 2004

(51) Int. Cl. H01L 21/50; H01L 21/44; H01L 23/48

(52) U.S. Cl. 257/690; 438/107; 438/686

(57) ABSTRACT

A method of connecting internal silver traces to external gold to produce a gold external side metal for a low-temperature co-fired ceramic package includes the deposition of a ruthenium dioxide cermet barrier layer between layers of gold and silver. An LTCC package constructed in accord with the inventive method has gold, ruthenium and silver layers that are parallel to the LTCC package surface and normal to and also electrically coupled to a conductive trace formed within the LTCC layers of the package.

### BACKGROUND OF THE INVENTION

1. Field of the Invention

This invention pertains generally to the field of microelectronic packaging, and, more specifically, to the provision of electrically conductive terminations onto Low-Temperature Co-fired Ceramic (LTCC) packages using silver conductors.

2. Description of the Related Art

In modern society, electronic devices have become ubiquitous. Everywhere we travel, we do so with the assistance and convenience afforded by these microminiaturized wonders. Watches, personal digital assistants, laptop computers, and cellular telephones are all recognizable and commonplace devices carried about by persons. However, as technology has permitted, these devices are not the only ones which may be carried with a person.

Many modern microelectronic devices are integrated or concealed within other devices or even within people. Pacemakers, hearing aids, automatic medication dispensers, bone growth stimulators, biological recorders and alarms, and even personal safety and alerting devices have become very prevalent within, on, or transported by people. It is extremely commonplace for many mechanical and even chemical devices to additionally include microelectronic devices, the electronics performing such diverse roles as timers, monitors, sensors, controls and a myriad of other functions. These fimctions may simply be more economical than a mechanical or chemical counterpart, but will often provide functions that would otherwise be impractical or impossible to achieve.

As can be recognized then, with the myriad of potential applications for modern electronic devices, there are similarly diverse needs for the performance, size, price, and the like of such devices. While cost is always included in any equation for considering an application, there are many situations where cost alone cannot be the only dictating factor. For example, while a consumer may not be terribly concerned when a portable CD player skips, a “skip” within a pacemaker or medication dispenser could be life threatening. Consequently, a technology suited for one application will probably not meet the needs of all applications.

In the field of miniaturized electronic devices, there exist a large variety of materials that have been preferred for different applications. Among these, copper and silver have played an extensive role. Copper and silver both have excellent electrical conductivity, are very malleable, and have consequently been used as common conductors of electricity. Unfortunately, silver also exhibits a tendency to migrate, particularly in the presence of moisture, electrical fields, and chemical contaminants or impurities such as salts, sulfurous compounds and the like. While still used frequently as the conductor in polymer circuit boards, silver is known to migrate sufficiently to create voids and short circuits when exposed to moisture. Many keyboards have permanently failed when beverages have been spilled, owing to the migration of the silver from the intended conductive patterns or traces.

Where circuitry is required to be of much higher reliability, of substantially smaller size, support higher power devices in small space, or carry very high frequency signals, lower cost plastic and copper circuit boards are frequently inadequate. In such instances, electronics manufacturers may turn to special refractory substrates. These substrates will often be composed of very special glass and ceramic materials that can withstand very elevated temperatures, are very rugged, and have a better thermal expansion match to typical silicon chips than polymer materials. For simple circuits, such substrates may include only a single layer of insulating material, and may have conductors on either one or both sides thereof. However, circuits are also possible and frequently implemented that may have many layers of conductors routing various electrical connections in an almost spaghetti-like fashion, often in a very small space. Other devices may frequently be mounted upon these substrates, and the connections may be between devices and also to other similar supporting wiring substrates. With the more recent advent of the special glass and ceramic tapes, wiring substrates may be constructed from a plurality of layers of tape, each layer carrying a wiring pattern thereon.

Using this technology, which is illustrated in prior art FIG. 1 as an exemplary illustration and without technical precision regarding dimensions or the specific details of the wiring patterns or devices, an LTCC package 1 is manufactured by printing a conductive ink upon individual layers 2-5 of tape to form desired circuit traces 7 thereon. The conductive ink may be referred to for the purposes of this disclosure as a cermet material, which refers to the combination of CERamic particles with METal. However, it will also be understood that the ceramic component may similarly include or be composed entirely of special glasses and fluxes as are known in the industry, which will typically form a suitable matrix within the conductor during the usual firing process. To make an ink from the dry glass, ceramic and metal powders that form the active components of a cermet paste, various solvents, polymers, and the like will be added thereto which permit the cermet paste to be printed through a screen, again as is known in the industry. Other patterning techniques are known and would be applicable herein. However, screen printing has been demonstrated over the years to offer a great deal of reliability and speed when working with these frequently very hard and abrasive pastes, thereby lowering the cost when compared to other competing techniques. Screen printed layers are frequently industrially referred to, and will be herein, as thick film layers, which are contrasted with typical electroplated or vacuum deposited layers that are most frequently substantially thinner, and are therefore known in the industry as thin film techniques. For many applications, the thick film techniques are better suited than thin film approaches.

The plurality of individual layers 2-5 are stacked together, upon each other, to form a laminate, and then the laminate is fired at elevated temperatures to cause the glass, ceramic, and metal particles to sinter and bind together to form a multilayer substrate. With even further advances, such techniques may be used to not only form relatively two-dimensional wiring boards such as illustrated in prior art FIG. 1, but may also be used with appropriate hole punching and the like to form three-dimensional structures, including containers, packages with deep wells therein, or the like. It is also possible to route conductors through the layers or entire structure, and to even bury other devices within the layers of tape. However, whatever is contained within the tape prior to firing must be able to withstand both the temperatures of the firing and the chemical compounds that will be present therein throughout the entire firing process.

When the substrate has been laminated and fired, it will typically be sawn from the tape. In many instances the sheet is much larger than a single device, and so may have many devices adjacent to each other. Similarly, the tape frequently includes various registration and alignment holes about the periphery of the individual LTCC substrates which must be separated from the final package. One common tool used for separation is a special diamond saw, which offers the durability to adequately cut these typically very hard and abrasive refractory substrates. When the LTCC package has been cut from a larger tape, the kerf formed by the saw, sometimes referred to as a saw street, will with some desired designs reveal circuit traces 7 at the edges of the substrate. These circuit traces are provided intentionally, and offer various electrical connection points for coupling to the circuit traces 7 within LTCC package 1. A conductive metal termination 8 will ordinarily be provided which enlarges the area for contact adjacent to the substrate, and thereby provides a more reliable finished product. Vias 9, which are holes through one or more of the layers 2-5 that are typically filled with electrically conductive material, are also provided to enable interconnection between the various layers of conductive traces 7. Where desired, various active and passive components 10 will then be mounted upon the laminated and fired substrate. Where desired, a cover 6 may be provided. In the event cover 6 is fabricated from an electrically conductive material, one more layer than illustrated in FIG. 1 will need to be provided above layer 2, and a brazing ring will typically be formed thereon. This is so cover 6 may fully enclose the components without shorting out conductive traces 7. As may be apparent, the resulting LTCC package 1, which is known in the art, is hermetic and durable, and will provide a very high quality, almost impervious and highly reliable package for both components 10 and conductive traces 7 therein.

In this application of high temperatures and complex chemistries present during firing, the corrosion resistance and high conductivity intrinsic to silver is very desirable. Within the confines of LTCC package 1, there is no exposure to moisture and contaminants that could otherwise lead to failure. The conductivity of the silver is exemplary, and cost for such an application, where very little silver is actually consumed, is minimal. Unfortunately, the use of silver as the conductive within the tape, whether in pure form or as an alloy, necessitates some type of interconnection external to the tape. It is this external connection that generally forms the subject matter of the present invention, and which has presented problems in the prior art.

As aforementioned, silver is known to migrate and may also be corroded. Consequently, there are many applications which demand materials other than silver. Another material that is used in very demanding applications is gold. Gold has good electrical conductivity, though not as good as silver, has better corrosion resistance, and has much better resistance to migration or contaminants. Unfortunately, gold at the time of this writing costs by weight more than fifty times as much as silver. In spite of the substantially greater price of gold, there are still applications that demand the characteristics and support the increased cost.

In order to better serve the marketplace, it is desirable to utilize silver as the internal conductor, benefitting from the lower cost and higher conductivity, while providing external terminations of gold. Unfortunately, such constructions, illustrated for exemplary purposes in prior art FIG. 1, have been determined to be plagued by another failure mechanism. Silver migrates through grain boundaries within gold and other materials, leaving behind voids that will result in poor circuit performance or complete failure. These voids are known as Kirkendall voids. When the objective is higher reliability and performance, gold and silver have been determined to be incompatible as adjacent materials. Another approach that will permit the use of silver conductors and gold terminations is desired.

### SUMMARY OF THE INVENTION

In a first manifestation, the invention is a method of connecting internal silver traces to external gold to produce a gold external side metal for an LTCC package. In accord therewith, a green tape is provided and then patterned with silver conductive material. The tape is then laminated and fired. Once fired, an individual LTCC package is separated from the laminate. During this process, the end of at least one conductive trace is exposed. Silver is then deposited upon the exposed end, followed by depositing ruthenium upon the silver deposit, and depositing gold upon the ruthenium deposit.

In a second manifestation, the invention is a selectively conductive substrate fabricated from at least one inorganic dielectric layer and at least one conductive trace patterned upon the at least one inorganic dielectric layer. The improvement comprises a ruthenium conductive material electrically coupled to at least one conductive trace, and a gold conductive material electrically coupled to the ruthenium conductive material. The gold material is isolated from diffusion with the conductive trace by the ruthenium conductive material.

In a third manifestation, the invention is a method of connecting internal silver traces to external gold to produce a gold external side metal for an LTCC package. According to this manifestation, a tape composed of refractory materials and organic binders is selectively perforated and then patterned with a silver conductive material. The tape is laminated and then fired. From the fired tape an LTCC package is separated, and during the separation step the silver conductive material is exposed. An elemental silver cermet paste is screen printed upon the exposed silver conductive material and fired to produce a fired silver cermet contact layer. A ruthenium dioxide cermet paste is screen printed upon the fired silver cermet contact layer, and then fired to produce a fired ruthenium dioxide barrier layer. An elemental gold cermet paste is screen printing upon the fired ruthenium dioxide barrier layer, and then fired, to yield a gold external side metal and silver bonding to the interior traces of the LTCC package.

In a fourth manifestation, the invention is a selectively conductive substrate fabricated from a multilayer refractory dielectric laminate. At least one conductive trace is patterned within the multilayer refractory dielectric laminate and extends to an exterior thereof. A screen-printed and fired ruthenium cermet conductive layer is electrically coupled and generally normal to the at least one conductive trace, and a screen-printed and fired gold cermet conductive layer is electrically coupled to and deposited adjacent the ruthenium conductive layer. The gold layer is isolated from the at least one conductive trace by the ruthenium cermet conductive material.

### OBJECTS OF THE INVENTION

Exemplary embodiments of the present invention solve inadequacies of the prior art by providing a printed and fired ruthenium barrier layer between silver conductive trace metal and gold termination material. A first object of the present invention is the provision of a high reliability, dense wiring substrate fabricated from refractory tapes, typically of glass and ceramic composition. A second object of the present invention is the fabrication of a wiring substrate using silver conductors therein. Another object of the present invention is the termination of a silver, glass and ceramic substrate with gold. A further object of the present invention is the fabrication of such substrate using thick film techniques of depositing pastes and firing. Yet another object of the invention is the provision of a substrate having the aforementioned characteristics that may be fabricated using materials and techniques that are already common in the industry.

### BRIEF DESCRIPTION OF THE DRAWINGS

The foregoing and other objects, advantages, and novel features of the present invention can be understood and appreciated by reference to the following detailed description of the invention, taken in conjunction with the accompanying drawings, in which:

FIG. 1 illustrates an exemplary prior art LTCC package from projected and exploded view to which the present invention may be successfully applied.

FIG. 2 illustrates a preferred embodiment LTCC package termination designed in accord with the teachings of the present invention from a partial and magnified cross-sectional view.

FIG. 3 illustrates a preferred embodiment method designed in accord with the teachings of the present invention by flow chart.

FIG. 4 illustrates an elemental analysis of prior art terminations using a scanning electron microscope (SEM) with energy dispersive spectrometry (EDS).

FIG. 5 illustrates an elemental analysis of the preferred embodiment package of FIG. 2 using a scanning electron microscope (SEM) with energy dispersive spectrometry (EDS).

### DESCRIPTION OF THE PREFERRED EMBODIMENT

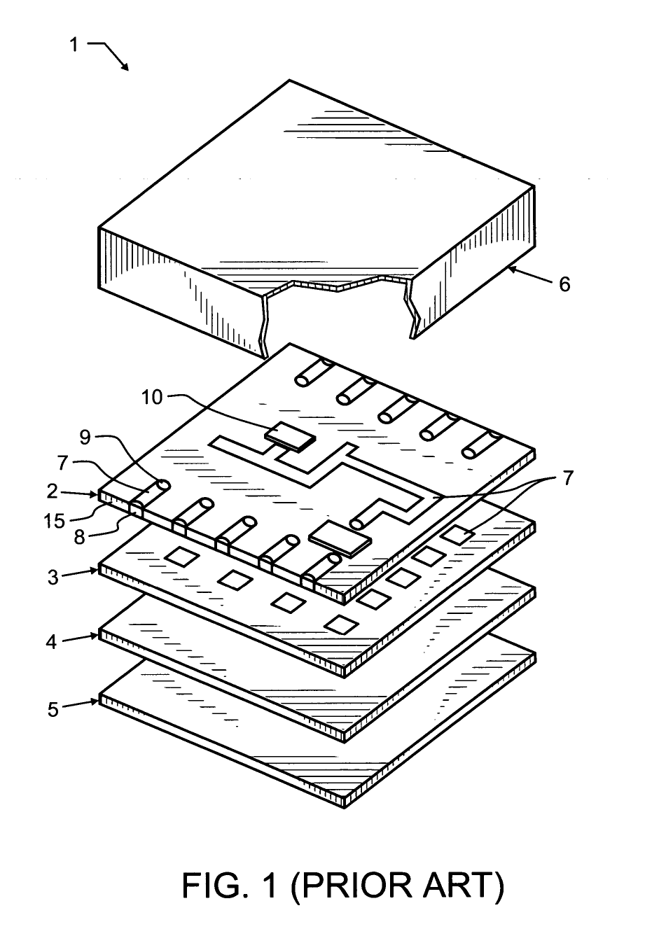

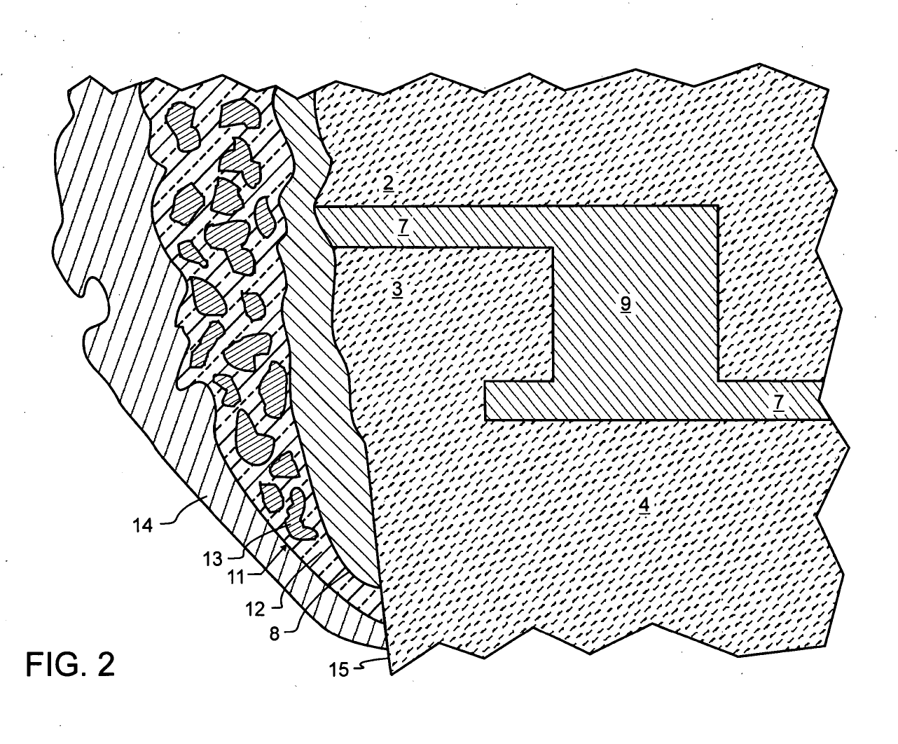

FIG. 2 illustrates a preferred embodiment of the invention, using the general structure of LTCC 1 of FIG. 1, including a multi-layer structure consisting of at least layers 2-4. It will be understood upon a reading hereof that the numbers of layers used in the application of the present invention is not critical, and the illustration of the jagged cut lines at the borders in FIG. 2 explicitly emphasizes this fact. As FIG. 2 also illustrates, after laminating and firing, the individual layers, such as layers 2-4 illustrated therein, will bond and sinter to each other, leaving no significant identification of the boundaries therebetween. However, conductive traces 7, which are formed on the surfaces of the discrete layers, tend to mark the original layer boundaries.

At the exterior edge of the layers 2-4 and in contact with one or more conductive traces 7, a layer 8 of conductive metal is preferably formed. Where elemental silver is used in the formation of conductive traces, layer 8 will most preferably also be formed using elemental silver. For the purposes of this disclosure, it will be understood that the conductive materials may include other non-conductive ingredients, such as the cermet paste components described herein above, and yet may still be referred to herein as elemental, assuming that the conductive metal used in the cermet composition is, in fact, elemental and not significantly alloyed or in the form of a multi-element compound either prior to or subsequent to the firing process.

While other compounds besides silver are known, palladium-silver alloys and platinum-silver alloys being such compounds, those skilled in the art will recognize that palladium and platinum are both substantially more expensive than silver. Nevertheless, it will be recognized by those skilled in the art that the present invention will not be limited solely to elemental silver, and may be extended to various silver alloys in certain circumstances by those skilled in the art upon a reading of the present disclosure.

Layer 8 is preferably provided along surface 15 of the substrate, which surface 15 is left by the sawing of the substrate from the fired tape. The action of layer 8 is to provide a relatively larger and more reliable electrical contact than presented by conductive trace 7. For those applications requiring a gold contact surface, artisans may be inclined to directly apply gold to this layer 8, or even instead thereof. However, when gold is applied immediately adjacent to silver, the silver migration produces voids within the silver which are known to disrupt or even fully prevent adequate conductivity. These voids, as noted herein above, are referred to as Kirkendall voids in recognition of one of the early pioneers in differential diffusion of one material into another. The prevention of such voids is a very complex problem, which has heretofore frustrated many very skilled artisans. The present inventors have discovered that a ruthenium dioxide layer formed between gold and silver prevents diffusion from occurring between the silver and gold. When properly fabricated, as illustrated in FIG. 2, the overall conductivity of the termination is essentially unaffected.

More particularly, a barrier layer 11 is preferably formed upon silver layer 8, comprising a matrix of refractory materials 12 and ruthenium dioxide particles 13 sintered therein. A cermet layer 14 of elemental gold may then be formed on top of barrier layer 11, essentially sandwiching layer 11 between layers 8 and 14. Because layer 8 is generally planar, with conductive trace 7 extending substantially normal thereto, and barrier layer 11 is parallel to and adjacent layer 8, and has a relatively small thickness between layers 8 and 14 relative to width (not visible in FIG. 2, but in FIG. 1) and height, the overall resistivity of barrier layer 11 is inconsequential for the operation of most circuits.

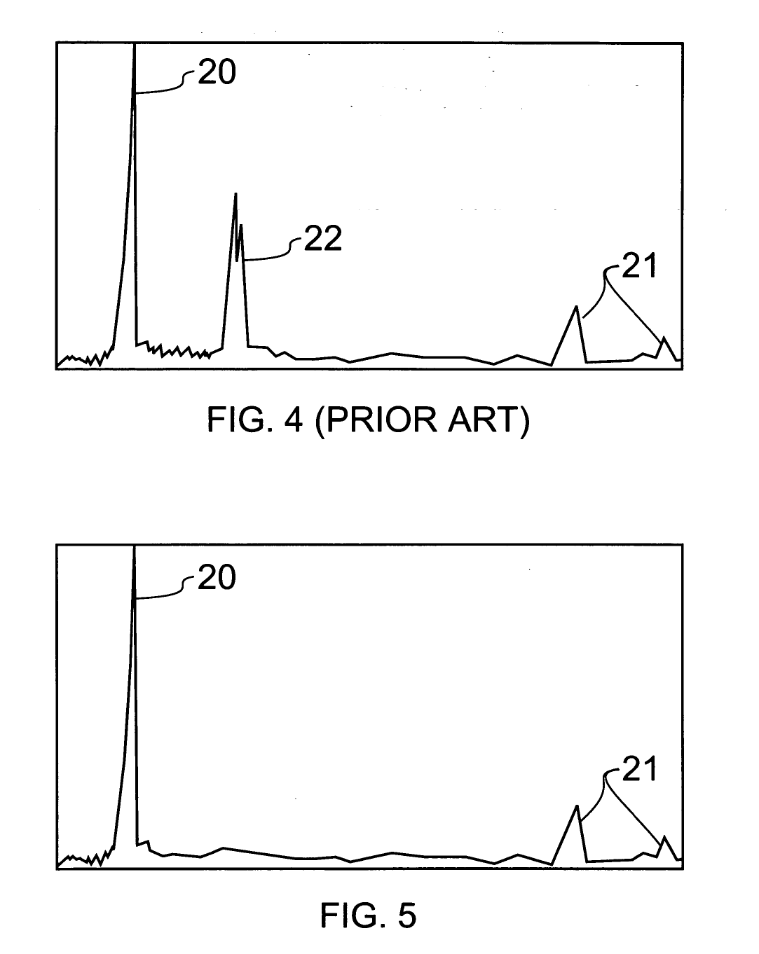

With a barrier layer 11 present, an external layer 14 of elemental gold may then be applied without the adverse impact of diffusion between silver and gold. FIG. 4 graphically represents the approximation of results of a scanning electron microscope (SEM) energy dispersion spectrometry (EDS) plot of a control assembled using an elemental gold layer 14 patterned immediately adjacent an elemental silver layer 8. Peaks 20 and 21 identify the substantial presence of gold. However, peak 22 detects significant silver that has diffused into the gold layer. In contrast to the presence of silver shown by the plot in FIG. 4, the present invention prevents diffusion. This is evidenced by the graphical representation of the approximation of results of an SEM EDS plot as shown in FIG. 5. In the present invention as illustrated for exemplary purposes in FIG. 2, the gold peaks 20, 21 are still present, but silver peak 22 no longer is present. In other words, silver has not diffused through the ruthenium dioxide barrier layer 11 of the present invention.

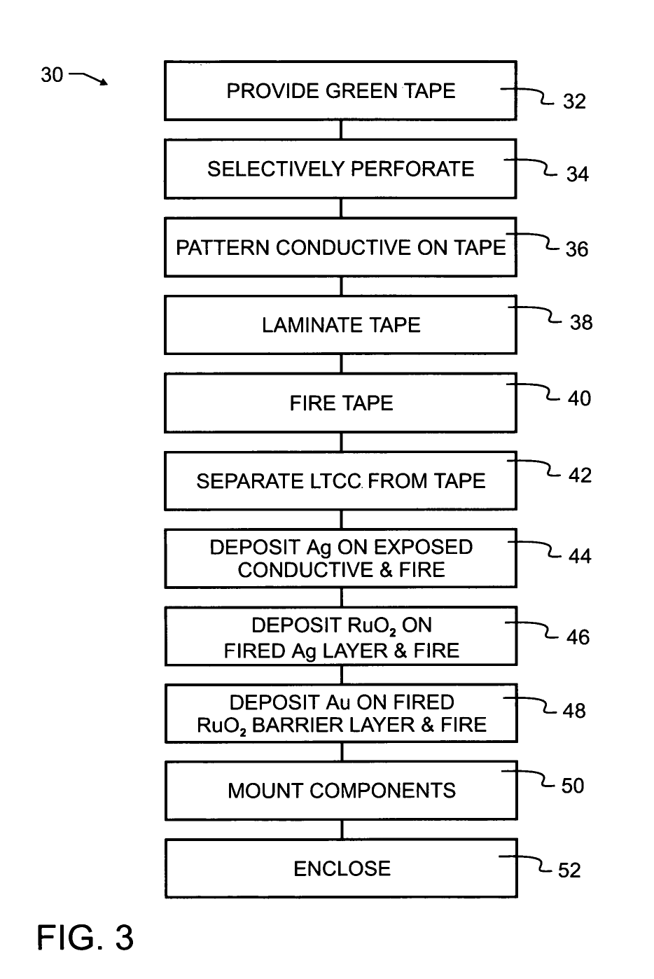

The preferred method of formation 30 of the embodiment of FIG. 2 is illustrated by flow chart in FIG. 3. According to the preferred method 30, a tape composed of refractory materials and organic binders is provided in step 32. As discussed herein above, such tapes are commonly referred to as green tapes, because the refractory materials are in a green, or pre-fired, state. These tapes are typically relatively pliable and readily worked. In this stage, the tape is readily selectively perforated at step 34, if so desired or required. Where a multi-layer circuit is to be fabricated, it will be most typical to include various vias 9 that extend through the dielectric tape material and into which conductive material may be placed prior to firing. Additionally, where three-dimensional packages are to be fabricated, it is also possible to perforate the tape with larger shapes removed therefrom. These larger openings or windows may be aligned from layer to layer, with a plurality of layers each having a window in alignment with other such windows. Upon firing, the windows may be used to form a cavity of substantially larger dimension than a via 9, and may serve as a chamber for other components such as components 10.

Once the tape is perforated, it will then be patterned with a silver conductive material in step 36. As discussed herein above, the patterning may occur using any of the various diverse techniques, though screen printing will often be used and may be considered exemplary, but not limiting, herein. The plurality of layers of tape are then laminated in step 38. Many techniques are known in the art for such lamination, and may include simple pressing, vacuum lamination, or others of a myriad of techniques. Most significantly however is the generation of good contact between layers 2-5, to avoid undesirable pockets of air or gas being entrapped therein which would destructively expand during heating, and the lack of sintering and bonding between layers that might occur even with very minute amounts of separation.

The laminated tape is then fired in step 40. Once again, the exact method used to fire the laminate is not critical, and will be dependent to some extent upon the composition of the tape and the instructions for firing associated therewith. From the fired tape an LTCC package is separated in step 42. While the separation technique may once more be achieved using diverse technologies, one common method is the sawing of the fired tape using a diamond saw or the like. During separation step 42, silver conductive material is necessarily exposed. Consequently, the method of separation should preserve the buried conductive traces sufficiently to permit subsequent coupling thereto.

An elemental silver cermet paste is then screen printed or otherwise deposited upon the exposed silver conductive material, and then fired to produce a fired silver cermet contact layer in step 44. This silver cermet paste may include very high percentages of silver, with only minor amounts of glass and/or ceramic compounds to provide optimal conductivity.

A ruthenium dioxide cermet paste is screen printed upon the fired silver cermet contact layer, and then fired to produce a fired ruthenium dioxide barrier layer in step 46. Using ruthenium dioxide typically requires somewhat higher levels of glass than attainable with silver. Since the glass or refractory is generally non-conductive and the ruthenium dioxide a weak conductor, this layer will have greater intrinsic resistance than either layer 8 or layer 14. However, in the geometries illustrated in FIG. 2, the resistance of barrier layer 11 therein between layers 14 and 8 will be very minimal, since the layer is thin and the area is large. This arrangement will consequently not generally affect circuit performance. As should be appreciated then, while layer 8 is not absolutely essential to the workings of the present invention, this layer 8 normal to trace 11 is most preferably formed to provide large contact area to barrier layer 11, to prevent the intrinsic resistivity of barrier layer 11 from interfering with the operation of most circuits. In contrast, the absence of layer 11 would tend to concentrate current flow in barrier layer 11 to the smaller contact area at the edge of conductive traces 7.

An elemental gold cermet paste is screen printed upon the fired ruthenium dioxide barrier layer, and then fired in step 48, to yield a gold external side metal and silver bonding to the interior traces of the LTCC package. Once again, the elemental gold cermet paste may be almost entirely gold, with very little refractory glass and/or ceramic therein. This gold layer then provides a very conductive, corrosion resistant, and readily bonded surface. Most preferably, and for the reasons already mentioned, gold layer 14 will also present much contact area with barrier layer 11.

Optionally, various active and passive components 10 may then be mounted in step 50. These components may include any of the diverse microelectronic devices such as, for exemplary purposes only and not limited thereto, integrated circuits, transistors, capacitors, inductors, resistors, filters, electromechanical resonators, and even other hybrid microelectronic packages or components. If desired, the LTCC package may then be enclosed in step 52, such as by the attachment of a cover 6 or functionally equivalent structure.

While not illustrated, those skilled in the art will also recognize that other processing steps may be applied to the present invention, typically subsequent to firing. Such steps may, for example, include additional coatings or layers designed for one or another specific application.

While the foregoing details what is felt to be the preferred embodiment of the invention, no material limitations to the scope of the claimed invention are intended. Further, features and design alternatives that would be obvious to one of ordinary skill in the art are considered to be incorporated herein. The scope of the invention is set forth and particularly described in the claims herein below.

We claim:

1. A method of connecting internal silver traces to external gold to produce a gold external side metal for an LTCC package, comprising the steps of:
providing a green tape;
patterning a silver conductive material into conductive traces upon said green tape;
laminating said patterned green tape;
firing said laminated green tape;
separating said LTCC package from said laminate and thereby exposing an end of at least one of said conductive traces;
depositing silver upon said exposed end of at least one of said conductive traces;
depositing ruthenium upon said silver deposit; and
depositing gold upon said ruthenium deposit.

2. The method of connecting internal silver traces to external gold to produce a gold external side metal for an LTCC package of claim 1, further comprising the step of coupling active and passive devices to said LTCC package.

3. The method of connecting internal silver traces to external gold to produce a gold external side metal for an LTCC package of claim 1, further comprising the step of selectively perforating said green tape.

4. The method of connecting internal silver traces to external gold to produce a gold external side metal for an LTCC package of claim 3, wherein said step of perforating further comprises forming at least one cavity region within said tape, and said step of laminating further comprises forming at least one cavity within said LTCC package from said at least one cavity region.

5. The method of connecting internal silver traces to external gold to produce a gold external side metal for an LTCC package of claim 1, wherein said step of separating further comprises sawing.

6. The method of connecting internal silver traces to external gold to produce a gold external side metal for an LTCC package of claim 1, wherein said deposited silver further comprises elemental silver with cermet paste.

7. The method of connecting internal silver traces to external gold to produce a gold external side metal for an LTCC package of claim 6, wherein said step of depositing silver further comprises the steps of:
screen printing said silver and cermet paste upon said exposed end of at least one of said conductive traces; and
firing said LTCC package to sinter said silver and cermet paste.

8. The method of connecting internal silver traces to external gold to produce a gold external side metal for an LTCC package of claim 1, wherein said deposited ruthenium further comprises ruthenium dioxide with cermet paste.

9. The method of connecting internal silver traces to external gold to produce a gold external side metal for an LTCC package of claim 8, wherein said step of depositing ruthenium further comprises the steps of:
screen printing said ruthenium dioxide and cermet paste upon said deposited silver; and
firing said LTCC package to sinter said ruthenium dioxide and cermet paste.

10. The method of connecting internal silver traces to external gold to produce a gold external side metal for an LTCC package of claim 1, wherein said deposited gold further comprises elemental gold with cermet paste.

11. The method of connecting internal silver traces to external gold to produce a gold external side metal for an LTCC package of claim 10, wherein said step of depositing gold further comprises the steps of:
screen printing said elemental gold and cermet paste upon said deposited ruthenium; and
firing said LTCC package to sinter said elemental gold and cermet paste.

12. A selectively conductive substrate fabricated from at least one inorganic dielectric layer and at least one conductive trace patterned upon said at least one inorganic dielectric layer, wherein the improvement comprises a ruthenium conductive material electrically coupled to said at least one conductive trace, and a gold conductive material electrically coupled to said ruthenium conductive material and isolated from said at least one conductive trace by said ruthenium conductive material.

13. The selectively conductive substrate of claim 12, wherein said at least one inorganic dielectric layer fturther comprises a glass and ceramic composition.

14. The selectively conductive substrate of claim 13, wherein said at least one inorganic dielectric layer further comprises a tape.

15. The selectively conductive substrate of claim 14, wherein said at least one inorganic dielectric layer further comprises a multi-layer tape.

16. The selectively conductive substrate of claim 12, wherein said at least one conductive trace further comprises silver.

17. The selectively conductive substrate of claim 12, wherein said at least one conductive trace is screen-printed and fired upon said at least one inorganic dielectric layer.

18. The selectively conductive substrate of claim 12, wherein said ruthenium conductive material further comprises a generally planar layer and said at least one conductive trace extends generally normal thereto.

19. The selectively conductive substrate of claim 12, wherein said ruthenium conductive material is screen-printed and subsequently fired.

20. The selectively conductive substrate of claim 12, wherein said ruthenium conductive material further comprises a cermet composition.

21. The selectively conductive substrate of claim 18, further comprising a silver cermet layer parallel to said ruthenium conductive layer and interposed between said ruthenium conductive layer and said at least one conductive trace.

22. The selectively conductive substrate of claim 18, wherein said gold conductive material further comprises a screen-printed and fired cermet layer deposited adjacent said ruthenium conductive material and isolated from said at least one conductive trace by said ruthenium conductive material.

23. A method of connecting internal silver traces to external gold to produce a gold external side metal for an LTCC package, comprising the steps of:
providing a tape composed of refractory materials and organic binders;
selectively perforating said tape to form at least one hole therein;
patterning a silver conductive material upon said tape;
laminating said perforated and patterned tape;
firing said laminated tape;
separating said LTCC package from said laminated tape and thereby exposing said silver conductive material;
screen printing an elemental silver cermet paste upon said exposed silver conductive material;
firing said elemental silver cermet paste to produce a fired silver cermet contact layer;
screen printing a ruthenium dioxide cermet paste upon said fired silver cermet contact layer;
firing said ruthenium dioxide cermet paste to produce a fired ruthenium dioxide barrier layer;
screen printing an elemental gold cermet paste upon said fired ruthenium dioxide barrier layer; and
firing said elemental gold cermet paste.

24. A selectively conductive substrate fabricated from a multilayer refractory dielectric laminate and at least one conductive trace patterned within said multilayer refractory dielectric laminate and extending to an exterior thereof, wherein the improvement comprises a screen-printed and fired ruthenium cermet conductive layer electrically coupled and generally normal to said at least one conductive trace, and a screen-printed and fired gold cermet conductive layer electrically coupled to and deposited adjacent said ruthenium conductive layer and isolated from said at least one conductive trace by said ruthenium cermet conductive material.

25. The selectively conductive substrate of claim 24 further comprising a silver cermet layer parallel to said ruthenium conductive layer and interposed between said ruthenium conductive layer and said at least one conductive trace.

26. The selectively conductive substrate of claim 25 wherein said at least one conductive trace further comprises silver.
